(19) United States
(12) Patent Application Publication
(10) Pub. No.: US 2022/0156425 A1
(43) Pub. Date: May 19, 2022

(54) TRANSFORMATIONS BETWEEN INFORMATION MODELS DESCRIBING A BUILDING AND ITS USE

(71) Applicant: Haahtela-kehitys Oy, Helsinki (FI)

(72) Inventors: Yrjänä Haahtela, Helsinki (FI); Ari Pennanen, Helsinki (FI); Markus Mikkola, Helsinki (FI); Erkki Teittinen, Helsinki (FI); Janne Ojala, Helsinki (FI)

(21) Appl. No.: 17/442,318

(22) PCT Filed: Mar. 23, 2020
(86) PCT No.: PCT/FI2020/050180

§ 371 Date: Sep. 23, 2021

(30) Foreign Application Priority Data
Mar. 25, 2019 (FI) 20195225

(51) Int. Cl. G06F 30/13; G06Q 50/08

(52) U.S. Cl. CPC G06F 30/13; G06Q 50/08

(57) ABSTRACT

A server, method and software, configured to: receive an information model describing intended function and a purpose and mode of use of spaces of a building serving the function of a user; transform the information model describing said function into an information model describing spaces of a virtual building and requirements for the building project; transform the information model describing the spaces of the virtual building and the requirements for the building project into an information model describing massing of the virtual building; transform the information model of the virtual building into its building elements and usage elements, whereby said virtual building corresponds to a physical building and its use. The virtual model of the building may be provided automatically and immediately based on setpoint information relating to the function of the user of the building, to provide information on effects of different choices before actual building design.

### TECHNICAL APPLICATION

One embodiment as described relates to a server, method and software between transformations of information models describing a building.

### BACKGROUND

In a building project, real estate development and/or real estate management, a large number of decisions must be made without knowing their consequences. For example, when defining an functional concept, the investment, usage, or for instance carbon footprint cannot be predicted. The information available at a decision-making time is completely different from the system or consumption information obtained as a result of designing of the building, and consequences of the outcome may not be predicted by the available means with a satisfactory accuracy. For instance, it has been found in American literature studies that a prediction made before designing corresponds to the outcomes with only a +/−30 percent accuracy.

Traditionally, experts have performed the design work giving sufficient input information to evaluate the consequences.

Designing requires a considerable work input, and is therefore slow. Without the customer's objectives set before designing and comparison of the designs with the objectives, designing has been found to be random.

Use of a virtual building as a development, design and control tool enables consideration of later realized consequences at the decision-making time. The virtual building may be used as setpoint information as such, and as input information.

Building-type specific registers have been formed based on statistical methods. In the extreme case, recently implemented projects are compared and provided as reference buildings.

Additionally, standardized configurations have been sought e.g. by making a new building similar to a previous building.

Statistical methods and reference projects are inaccurate to solve a specific identified problem. Standardization of the configurations limits the options, and standard configurations are inflexible to meet constantly changing needs in different environments.

One generally used aid in building design is a building information model, BIM. BIM is an aggregate of information for the entire life time of a building and a building process in a digital form. The information model also involves determining a geometry of the building and presenting it three-dimensionally for the purpose of visualization and various simulation needs. Thus, BIM produces building designs digitally, i.e. virtually.

However, BIMs require a full work input from designers, i.e. they are created as a result of expert work, and their production takes a long time.

BIM or corresponding virtual building design software are largely design aids. BIMs are rather databanks for design options. For example, a designer makes a decision about a desired window with relation to a façade, and this information is later available for use in exactly the same form, possibly resorted. Thus, BIMs only return the information fed into the model.

### SUMMARY

This summary is provided to introduce a selection of concepts in a simplified form, which are further described below in the detailed description. This summary is not intended to identify essential or critical features of the claimed subject matter or to limit the scope of protection of the claimed subject matter.

It is an object to provide transformations between information models describing a building and its use. The objects are achieved by the features of the independent claims. Some embodiments are described in the dependent claims.

One aspect comprises a server, configured to: receive an information model describing intended function and a purpose and mode of use of spaces of a building serving the operation of a user; transform the information model describing said function into an information model describing spaces of a virtual building and requirements for the building project; transform the information model describing the spaces of the virtual building and the requirements for the building project into an information model describing massing (i.e. geometry of the building) of the virtual building; transform the information model describing the massing of the virtual building into its building elements and usage elements, whereby said virtual building corresponds to a physical building and its use. In one embodiment, the virtual model of the building is provided automatically and immediately by the server based on setpoint information relating to the function of the user of the building. Thereby, information is obtained on effects of different choices before actual building design. This may also provide and enable setpoint information to control the designing.

In one embodiment, in addition to the above-said or alternatively, the server is further configured to determine in the transformation, as a requirement for the spaces and the building project, the size, purpose and properties of the space on the basis of said function. Thereby, the needed size, purpose and properties of the space may be determined on the basis of the intended function.

In one embodiment, in addition to the above-said or alternatively, the server is further configured to determine the number of the spaces on the basis of volume of said function, or on the basis of volume and time of use. The number of the spaces corresponding to the function may thereby be defined.

In one embodiment, in addition to the above-said or alternatively, the server is further configured to determine shared use of the spaces. The shared use of the spaces may combine the spaces to provide more efficient utilization rates and, if necessary, improve flexibility of use through more versatile and possibly larger spaces.

In one embodiment, in addition to the above-said or alternatively, the server is further configured to mass the virtual building on the basis of the properties of the spaces and the number of stories and location of certain spaces as modelled from the purpose of use. Thereby, the virtual building may be determined as an architectural mass.

In one embodiment, in addition to the above-said or alternatively, the server is further configured to determine systems of the building on the basis of the virtual building. For example heating, air conditioning and electrification may be configured for the virtual building.

In one embodiment, in addition to the above-said or alternatively, the server is further configured to determine consumption for the use phase of the building on the basis of the virtual building. The quantity of the use-phase consumption for a certain time period may be defined on the basis of the virtual building.

One aspect comprises a method, comprising: receiving an information model describing intended function and a purpose of use of spaces of a building serving the function of a user; transforming the information model describing said function into an information model describing spaces of a virtual building and requirements for the building project; transforming the information model describing the spaces of the virtual building and the requirements for the building project into an information model describing massing of the virtual building; transforming the information model describing the spaces of the virtual building and the requirements for the building project and its massing into its building elements and usage elements, whereby said virtual building corresponds to a physical building.

One aspect comprises a computer program, including programmable code which, when executed by a server, is configured to perform the method according to the preceding aspect.

Many of the features relating to the subject matter will be better illustrated and understood by reference to the following detailed description considered in connection with the accompanying figures.

### DESCRIPTION OF THE FIGURES

The present description will be better understood from the following detailed description presented with reference to the accompanying figures, wherein:

FIG. 1 is a block diagram illustrating a server and a system for performing transformations of information models describing a building according to one embodiment;

FIG. 2 is a block diagram illustrating a transformation of information models from function into a space and requirements for the project according to one embodiment;

FIG. 3 is a block diagram illustrating a transformation of information models from functions into spaces according to one embodiment;

FIG. 4 is a block diagram illustrating a transformation of information models concerning shared use of the spaces according to one embodiment;

FIG. 5 is a block diagram illustrating a transformation of information models from massing of the space volume into a building according to one embodiment;

FIG. 6 is a block diagram illustrating a transformation of information models to determine systems for the building according to one embodiment; and

FIG. 7 is a block diagram illustrating a transformation of information models for modelling consumption for the use phase of the building according to one embodiment.

Like references are used to designate like parts in the accompanying figures.

### DETAILED DESCRIPTION

The detailed description presented below in connection with the accompanying figures is intended as a description of the present embodiments, and is not intended to represent the only possible forms in which the present example may be constructed or utilized. However, corresponding or equivalent functions and structures may be implemented by different examples. In the description, reference is made to the accompanying drawings which illustrate, by way of example, transformations between information models describing a building and its use.

In one embodiment, a server performs a set of transformations between information models describing a planned real property and its use. The server receives input information fed by a user and transforms it into another form. This input information may be utilized as such or further as input information for internal transformations in the system.

In the transformation, the server is configured to transform an information model describing function of a building into an information model describing spaces of the building. The transformation may relate to requirements for the building project and their purpose of use, whereby the server transforms the function of the building to also correspond to the requirements and purpose of use of the building project. The server is configured to perform a transformation in which the information model of the spaces is transformed into an information model relating to massing of the building. The server is configured to perform a transformation in which the building is transformed into an information model describing the building elements. In addition, the server may perform a transformation in which the building is also transformed into use-related consumption describing the use of the building.

Traditionally, the transformations and describing their outcome in another aspect have required expert work. The transformations according to the embodiment enable automatization and prediction for analyses and designing regarding decision-making in a project, especially with a sufficient accuracy.

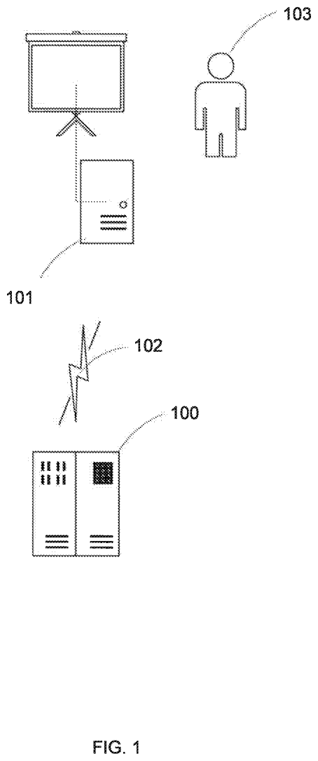

FIG. 1 illustrates a connection 102 of a terminal device 101 used by a user 103 with a server 100. The server 100 may be for example a workstation, a distributed computer system, a cloud service, or a single workstation or a single computer. The user 103 feeds necessary input information to the terminal device 101. The user 103 feeds the function of a planned building to the terminal device 101. The terminal device 101 forwards this information to the server 100 via the connection 102. The server 100 processes the information and performs transformations for the planned real property and its use between information models. The server 100 sends to the terminal device 101 the information models generated on the basis of the transformations, configured as building elements for implementing the functions and events by building of the building elements. The server 100 is configured to provide information models on the basis of which the building may be realized. For example, teaching of 600 students in Jätkäsaari is described, i.a., as a list of spaces of the building, serviceability requirements for the spaces, such as sound insulation, the number of stories of the building and ratios between the sizes of the stories, and elevator waiting time, and further as building elements, such as a window, a brick dividing wall, supply air ducts and an emergency notification system, which are needed to provide the serviceability; further, it describes tasks needed for example for designing and servicing the building elements, and use-phase consumptions and tasks which are ultimately needed to maintain the conditions and systems needed for the function.

In one embodiment, the terminal device 101 and the server 100 are a single computer or information system, whereby a separate connection 102 is not necessarily needed within or between the same information unit.

The server 100 is configured to perform the functions illustrated in the following figures by receiving input information, performing calculation and providing output information. The input information and output information may function as the basis for preceding and/or subsequent transformations of the server 100.

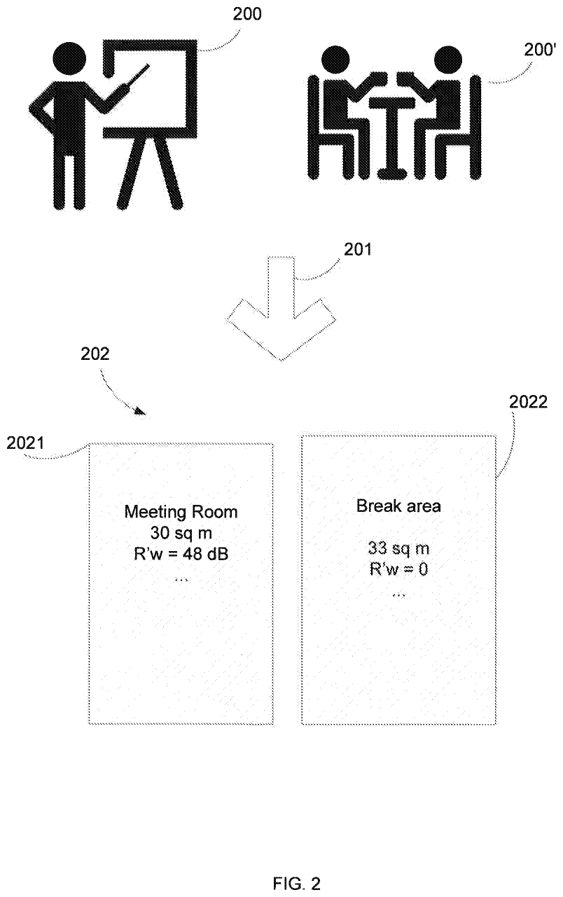

FIG. 2 is a block diagram illustrating a transformation 201 of information models from function 200,200′ into a space 202 and requirements for the project according to one embodiment. The server 100 is configured to transform an information model describing intended and specified function 200 of a building into an information model representing a space 202 of the building.

The size and nature of the space 202 is automatically determined on the basis of the transformation 201 of the server according to the internal function 200 and events of the space. For example, meeting work in negotiation is an event, as well as sleeping. In a case where 6 persons would be negotiating, the server 100 is configured to provide a space 202 requiring a surface area of 14 m². People consume oxygen and produce carbon dioxide, so it is determined that air should be replaced in the space 4.5 times per hour. If meeting guests would also want to rest in a bed in the middle of negotiation, in the new operating situation the server 100 would be configured to provide a space of 32 m2, an air conditioning noise level of 28 decibels instead of the earlier 33 dB, and a sound insulation of 56 decibels for the space instead of 48 dB. The description of the space 202 is generated as an functional information model, and properties of the space are output as an information model in a specified form. There may be numerous space properties generated by the server 100, for example over a hundred. In the input information model, the internal operation of the space is described as events and their quantities (an event driver), such as meeting work for 6 persons, and each event has property functions based on the quantity or quality of the event, which functions will be used as the basis for defining property requirements for each event. Performance requirements for the space are defined on the basis of the property-specific functions, such that the collective properties of the space enable all the events taking place in the space.

According to one embodiment, transformation of the internal operation 200 of the space 202 into space properties may be carried out as follows:

A. Input information:
1. The internal operation 200 of the space 202 is described as events. The event may be, for example, student work. The event takes place in the space 202.
2. The event has a driver corresponding to the serviceability of the space 202, for example the number of students.
3. Each event includes value functions for the essential space properties in terms of its implementation, for example room area. Thus, the space properties may be described as mathematical functions operating as the basis for algorithms.
4. Functions are defined for each space property type to combine the values of event level properties into the properties of a space.

### B. Calculation:

5. A first step of the calculation comprises calculating values of the event level value functions according to a driver of each event. For example, the surface area required by student work of 30 students is calculated with the value function A=30*1.5 m2−45 m2.
6. A second step of the calculation comprises combining values of the properties of the events by means of a space-property specific function to define the space properties. For example, the values of room areas for different events are combined by means of a sum.
   C. Output information
7. A list of the space properties of the space 202 is provided as the output.

In the embodiment of FIG. 2, the server 100 receives information models describing operations 200,200′, for example a teaching space 200 and a break space 200′. Additionally, quantities for the operational volumes are defined for the spaces. The server 100 performs the transformation 201 on this basis. Consequently, the server 100 proposes an operating space 2021 of a specific size and another operating space 2022 as the space 202 of the building.

In one embodiment, calculation of the number of the spaces 202 proceeds as follows:

D. Input information:
8. A hierarcal model is generated to describe the function of the occupant, including for example the levels of business line/functional sector, function, and process—which may be illustrated with the hierarchy office, information work, independent information work.
9. The functional levels have one or more drivers.
10. Typically, values of the drivers of the lower levels are determined as a function of values of the upper levels.
11. In the model, the processes reserve spaces 202, for example office rooms.
12. The space 202 has a driver describing the volume of the function 200, for example a quantity of meetings using the office rooms; an co-driver describing a typical unit of the function 200, for example a quantity of persons working in one office room; and a space driver regulating the event drivers of internal events in the space 202, for example the number of persons in the office room.

### E. Calculation:

13. In a simplified case, the number of the spaces 202 is calculated as a quotient of the driver describing a total functional volume and the co-driver describing the unit volume of the function 200.
   F. Output information
14. A list of the spaces 202 and their number is provided as the output.

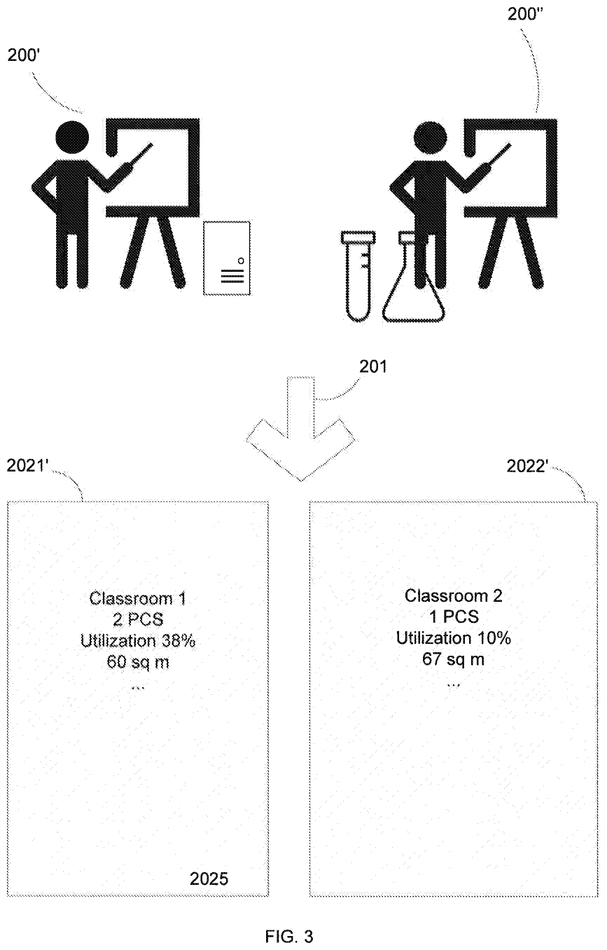

FIG. 3 is a block diagram illustrating a transformation of information models from functions 200 into spaces 202 according to one embodiment. In the embodiment of FIG. 3, the server 100 is configured to perform a transformation 201 by which functions 200 are transformed into spaces 202 as to their parameters.

The server 100 generates an information model for space utilization of the operating processes. On the basis of the information model for space utilization, the server 100 models the number of the spaces 202 according to the volume and use of time of the operating processes. For example, the total number of rooms of a hotel sets targets for the volume of meeting services, for example for the number of meetings and the number of persons. Time is recognized as a production factor. The time of an operating process includes for example teaching time given to a student, time spent by a dentist for a certain treatment, duration of a meeting, or time used for heat quenching of steel. The server 100 compares the time of the processes with a preferred time for the spaces 202 to be in use, and models the number of the spaces 202.

In one embodiment, calculation of the number of the spaces 202 supplemented with the temporal duration of the operation and capacity of spaces proceeds as follows:

G. Input information:
15. A model is generated for function of the user, including for example the levels of business line/functional sector, function, and process—which may be illustrated with the hierarchy office, information work, independent information work.
16. The functional levels have one or more drivers.
17. Typically, values of the drivers of the lower levels are determined as a function of values of the upper levels.
18. In the model, the processes reserve spaces 202, e.g. a meeting room.
19. In difference to the simplified calculation, the processes also have a temporal duration, for example the length of the meetings.
20. As above, the space 202 has a driver describing the volume of the function, for example a quantity of meetings using the meeting rooms, an co-driver describing a typical unit volume of the operation, for example in the meeting room type the number of participants in average meetings, and a space driver regulating the event drivers of internal events in the space 202, for example the seat number in the meeting room.
21. Additionally, the meeting room is associated with information indicating which proportion of the temporal load of the process relates to this meeting room, and space capacity information and maximum utilization rate of the meeting room.

### H. Calculation:

22. A first step comprises calculating the total load relating to the space 202 as a product of the process drivers, the temporal load of the process and load proportion of the space 202, and a total useable capacity of the space 202 as a product of the co-driver, the temporal capacity and the maximum utilization rate of the space 202.
23. The number of the spaces 202 is calculated here as a quotient of the temporal total load and total usable capacity relating to the space 202.
   I. Output information

A list of the spaces 202 and their number and expected utilization rate is provided as the output.

In the embodiment of FIG. 3, the server 100 performs a transformation 201 by which functions 200 are transformed into corresponding spaces 202. Function 200″ relates to teaching requiring information technology and 4 time units for the teaching event. Function 200″′ relates to teaching requiring chemistry and 3 time units. As a result of the transformation 201, the server 100 provides two separate spaces 2021 and 2022. Space 2021 would correspond to function 200″, and it would have a utilization rate of 38% and 60 square meters. Space 2022 would correspond to function 200″′, and it would have a utilization rate of 10% and 67 square meters.

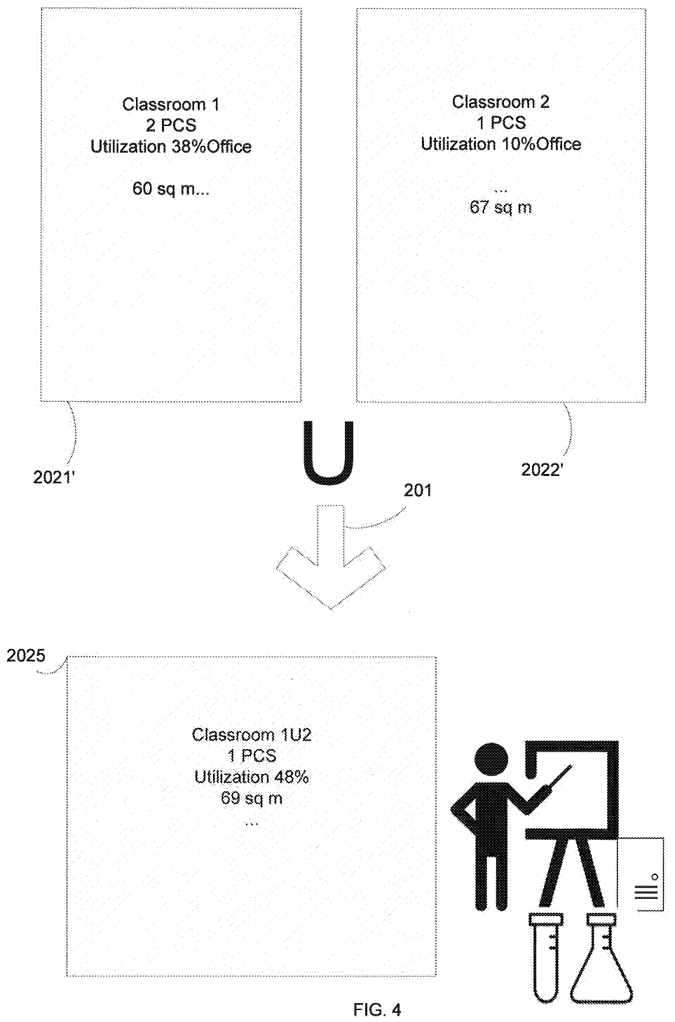

FIG. 4 is a block diagram illustrating a transformation 201 of information models concerning shared use of spaces 2021′,2022′ according to one embodiment. The server 100 is configured to perform a transformation 201 enabling the utilization of shared use of the spaces 2021′,2022′. For example, if two operators would both want a teaching space of 60 m2 with a utilization rate of 10%, 120 m2 of space will be needed. If they would agree on shared use, there will be needed one space of 60 m2 with a utilization rate of 20%.

The server 100 recognizes similar spaces 2021′,2022′ reserved for different functions of the owner and/or user of a planned building. The server 100 proposes shared use of the spaces 2021′,2022′ when the spaces have unused temporal capacity. For example, general teaching of a first language may use the same general teaching space with the teaching of mathematics. Shared use of the spaces 2021′,2022′ is automatically modelled at the server 100 by arranging the events taking place in the spaces 2021′,2022′ into a combination enabling all the operations 200 located in the space 202. This ensures that the surface area and properties of the space 202 correspond to all modes of use. For example, science teaching is mainly general teaching, but a demonstration desk will be needed for practical lessons. At the server 100, the user may reserve a general teaching space for use of the building and supplement its event structure with practical science lessons. The system of the server 100 optimizes the total need for the general teaching spaces and forms an internal description of the spaces 202 on the basis of the space reservations for general teaching spaces. For a general teaching space or general teaching spaces involving a space reservation for science teaching, the system supplements the general teaching space with a practical science lesson event thus creating the union of general and science teaching. On the basis of the point above, the space 202 will also be supported by the space properties.

In the embodiment of FIG. 4, the server 100 performs a transformation 201 by which spaces 2021′ and 2022′ are combined into space 2025. The server 100 recognizes that spaces 2021′ and 2022′ are combinable in terms of their functions and spaces. The server 100 changes the properties of the single space 2025, for example enlarges the area, to correspond to the combined operational needs. The utilization rate of the shared space 2025 increases in the example to 48%, but its size in square meters is only 69. In addition, the space 2025 virtually takes into account the chemistry and information technology equipment needed in the example in the size and utilization rate of the space 2025.

In one embodiment, defining the list of spaces proceeds as follows:

J. Input information:
24. Spaces 202, their exact number and utilization rate.
25. Space drivers for the spaces 202, events, drivers for the events and corresponding values of the value functions for the space properties.
26. Information on the preconditions for shared use of the spaces 202, for example whether the shared use of the space 202 is allowed.

### K. Calculation:

27. The spaces 202 are grouped according to the preconditions for shared use.
28. The spaces 202 are grouped according to titles and space drivers.
29. Similar spaces 202 with free temporal capacity are combined. For example, if 0.4 meeting rooms for 20 persons and 1.2 meeting rooms for 10 persons are needed, 1 meeting room for 20 persons and 1 meeting room for 10 persons will be formed.
30. A combination is formed of the events of the combined spaces 202.
31. The space properties of the space 202 are calculated according to point B.

### L. Output

32. An optimized number of the spaces and expected utilization rate of the optimized spaces.
33. Space properties of the optimized spaces.

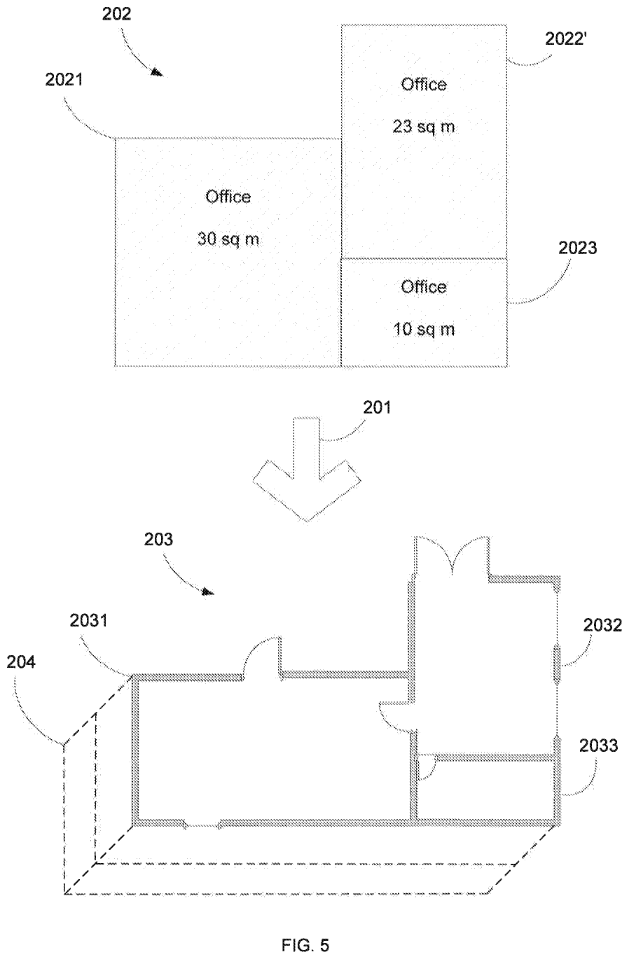

FIG. 5 is a block diagram illustrating a transformation of information models from massing of the space volume 202 into a building 203 according to one embodiment. The server 100 is configured to generate a virtual building 203 on the basis of the space 202.

In the system of the server 100, architectural massing of the building is based on the properties of the spaces 202, the number of stories 204 modelled from the purpose of use of the building, and location of certain spaces for example at a street level, in a basement or possibly in the highest story. The server 100 determines the input values described above on the basis of the properties of the spaces 202 as previously determined. Such properties relating to the input values for massing are for example need of natural light in the space, absence of pillars in the space (span), height of the space, etc. The server 100 algorithmically models the architectural massing of the building. The modelling output gives the sizes of the stories, heights of the stories, surface area of the envelope, indication of the size of basements, and other such quantitative information that is normally interpretable from an architectural sketch.

In the embodiment of FIG. 5, the server 100 is configured to perform the transformation 201. The space 202 is thereby transformed into the building 203 with rooms 2031, 2032 and 2033 corresponding to spaces 2021, 2022′ and 2023. The stories 204 of the building are provided according to the parameters generated as a result of previous transformations, or alternatively as fed. Likewise, estimates for the elements of the building 203, such as doors and windows, envelope, floor and roof structures, are provided for the building 203.

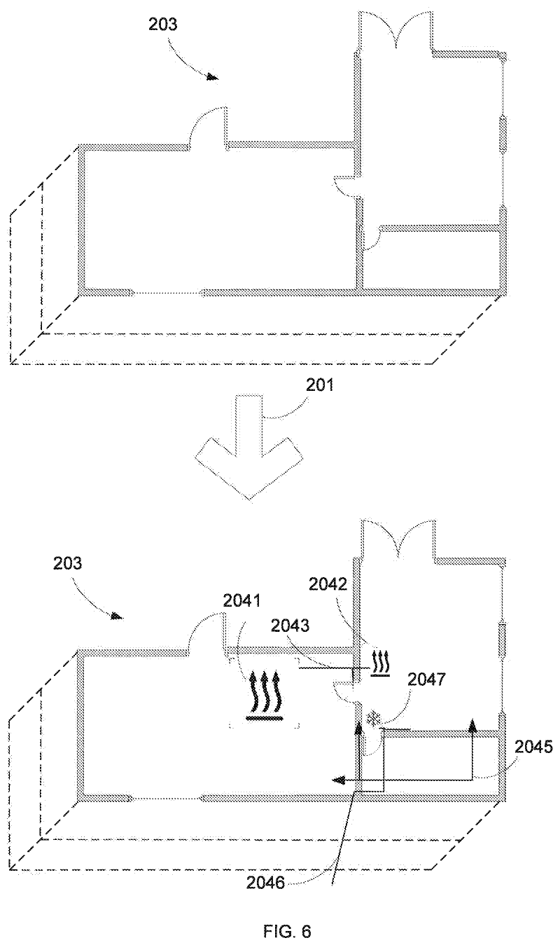

FIG. 6 is a block diagram illustrating a transformation 201 of information models to determine systems for the building according to one embodiment. The server 100 is configured to model the necessary systems for the building 203, such as heating, air conditioning, electrification, etc.

The system information model describes the conditions of the space environment, for example temperature, loading capacity and undisturbed supply of electricity in the space. In construction, the properties are provided by means of the systems of the building. For example, a request that the temperature of a space would not rise to an uncomfortable level is realized by means of a cooling system, and a request for sound insulation is realized by means of a dividing wall system designed for that purpose. The system of the server 100 is configured to virtually and quickly model the systems of the building. For example, the lighting system (the number of light fixtures, lumen values, electricity interface power, wires, circuit breakers) is modelled on the basis of the size of the spaces, the mode of use, and lighting requirement (LUX) for the space. The output of the transformation 201 gives an extensive system description according to the desired serviceability of the building 203, i.e. a building element model (pillars, footings, exterior walls, reserve power generators, cooling units, etc).

In one embodiment, the system also models the tasks required in order to produce the building. The tasks involve resource use that is necessary but is not part of the physical building. The tasks include for example architectural design, construction site management, tower crane services and construction site energy.

In FIG. 6, the server performs a transformation 201 by which the building 203 is supplemented by modelling of the systems. The system models the heating 2041 and 2042 to be suitable for corresponding spaces and parts of the building. In the example, the heat requirement for one of the spaces is lower, which the system estimates through lower-scale heating 2042. The system also models the cooling 2047 for the common space on the basis of the modelling. Air conditioning 2045 and electrification 2046 and 2043 are also modelled to be suitable for the spaces and the building.

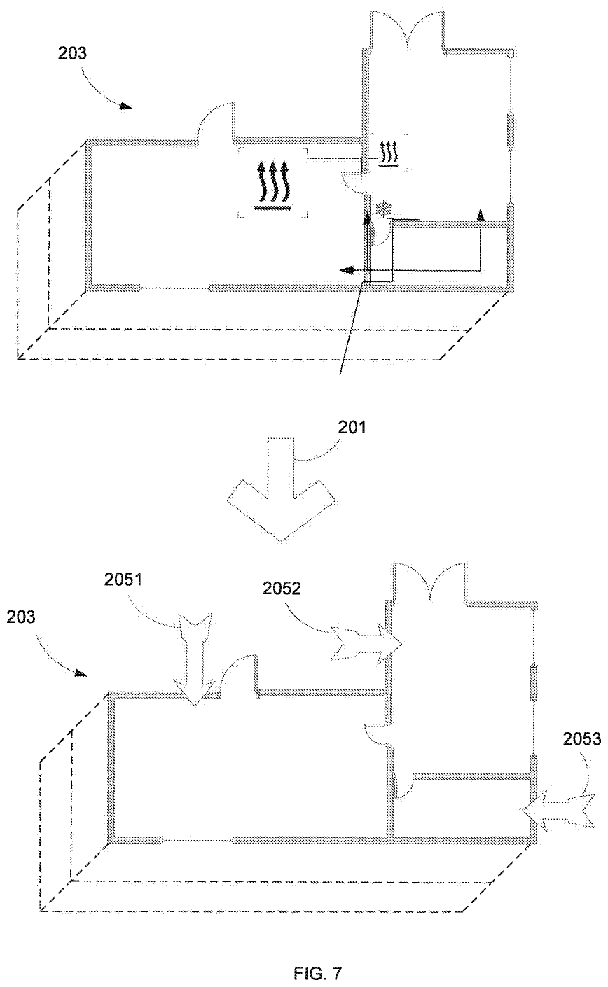

FIG. 7 is a block diagram illustrating a transformation 201 of information models for modelling the consumption for the use phase of the building according to one embodiment. The server 100 is configured to define space specific consumption 2051, 2052 and 2053 of the building for a certain time period.

The system information model describes the conditions of the space environment, for example temperatures, loading capacity and undisturbed supply of electricity of the spaces, and times of use and utilization rates of the spaces. When the building is being used, the conditions of the spaces are preserved by the systems of the building (cooling system, heating system, exterior wall) and by services (cleaning, maintenance, meeting refreshments). The system is configured to virtually immediately model the use-related consumption of the building. The consumption includes for example yearly electric energy, heating energy, work hours for cleaning, work hours for maintenance, and materials for the use.

The system is configured to identify the service life of the building systems. The information model automatically models system consumption in the maintenance and repair program over a time for which the building may be preserved in its original service condition (for example, the heating substation is replaced after 15 years from completion of the building).

In FIG. 7, the server 100 performs a transformation 201 for modelling the consumption 2051, 2052 and 2053 of the modelled building. The consumption 2051, 2052 and 2053 is modelled on the basis of the information models described in the previous embodiments.

In the following, one embodiment and example of a transformation 201 of a virtual building will be presented. The embodiment involves specifying the serviceability of the virtual building and modifying the massing of the virtual building.

The function of the modelling algorithms for the virtual building is described in this embodiment by way of varying the default values for modelling, whereby the information model automatically provides a new virtual building with new default values.

The user has requested the information model to model a high school for 500 students and a parking facility for 100 cars. The information model automatically models a virtual building having a surface area of 8 968 gross square meters. The massing algorithm provides a building with five stories, one of them being a basement.

The algorithms determining the serviceability of the building have determined that the food supply involves 552 persons/day (students and teachers). Meals are delivered from a central kitchen to the school's serving kitchen where the food is warmed up and served.

Both of the massing algorithms and serviceability describing algorithms simulate planning of the project for the customer's processes as well as the architectural and engineering design of the building immediately following the description of the needs of the user/owner of the building, and thus the virtual building is modelled before designing of the building begins.

In the example, the default values of the model are varied while monitoring the effect of the variation on some parts of the virtual building and on the use-phase consumption.

### Modification to Massing of the Building

The ground-water surface on the lot is close to the ground plane, and the owner (municipality) wants to test the building without a basement. Secondly, the local plan requires six stories overground, so one story is added to the building.

### Modification to Serviceability of the Building

Decision-makers of the municipality propose that the kitchen of this high school will be turned into a central kitchen where food is prepared from ingredients. The number of servings is increased to 1 000 servings, such that the kitchen of the high school can also serve the serving kitchens of the nearby elementary schools.

### Modifications Made by the Algorithms to the Virtual Building

1. The total size of the building is increased by 236 gfa. The model has been modified as follows:
the sizing of the central kitchen as compared to the previous serving kitchen is 78 m2 larger;
increasing the number of stories leads to a larger number of staircases, elevator shafts and technical shafts.
   2. Earthwork has been modified as follows:
the amount of soil extraction decreases by 11 400 m3 as the basement is omitted;
1 260 m2 less sheet pile wall is needed to support the construction pit. The clay soil beneath the ground-water surface could not have resisted falling into the basement pit without support.
   3. The length of the pillars of the building has increased by 4% due to a narrower mass of the higher building.
   4. The amount of exterior wall has been increased by 360 m2, i.e. 9%. The design configuration distributions for the exterior wall have been modified:
Previously, the algorithms determined that designing of mass in the basement underground would have been more efficient. When the spaces massed underground were massed into the visible frame, it follows the visible mass designing principles.
Adding a story “slenderizes” the building, which also increases the amount of exterior wall.
Previously, the algorithm designed about 22% of the exterior wall as a waterproof concrete earth pressure retaining wall (basement). In the new situation, all the exterior walls correspond to the normal visible façade configurations of the high school (partly façade elements, partly plastered brick cladding).
   5. The heating power requirement for the building has increased by 100 kW (about 6%), and the cooling power requirement has increased by about 4%:
The larger exterior wall increases the conduction of heat through the exterior wall in wintertime.
For the same reason, the number of heat emitters (radiators, radiant ceiling panels) has been increased by about 9% to 259.
Appliances of the central kitchen generate heat that must be removed by means of a cooling system.
   6. The electric power requirement for the building has been increased by 80 kW (about 15%):
The central kitchen with a larger number of servings needs more electric power than the serving kitchen.
Cooling of the central kitchen is implemented in the model by means of electrically operated water coolers.
   7. The mobile crane lifting time at the construction site has been increased by 60 productive hours (7%). Adding a story has increased the lifting height during construction.
   8. Electric energy consumption for the use phase of the building has been increased by 190 000 kWh (20%):
Appliances of the central kitchen with a larger number of servings consume more electricity than the serving kitchen.
Increased cooling of the central kitchen consumes more electricity.

The system of the server 100 comprises software configured to perform the functions according to the above-presented embodiments, for example the transformations 201 between information models as described in the embodiments. The server 100 comprises one or more processors as well as memories configured to execute the software. Additionally or alternatively, the server comprises programmable logics configured to perform the functions according to the above-presented embodiments.

All ranges or device values presented herein may be extended or modified without losing the intended effect and efficiency. In addition, any embodiment or feature may be combined with another embodiment, unless explicitly disallowed.

Although the subject matter has been described using specific structural features and/or functions, it is to be understood that the subject matter defined in the accompanying claims is not necessarily limited to the specific features or functions described above.

Rather, the specific features and functions described above are presented as examples of implementing the claims, and equivalents of other corresponding features and functions are intended to be within the scope of the claims.

It is to be understood that the benefits and advantages described above may relate to one or several embodiments. The embodiments are not limited to those that solve any or all of the stated problems or to those that have any or all of the stated benefits and advantages.

The steps of the methods described herein may be carried out in any suitable order, or simultaneously where appropriate.

Additionally, individual steps may be deleted with any method without departing from the spirit and scope of the subject matter as described herein. Aspects of the examples described above may be combined with aspects of any other example without losing the intended effect.

The term “comprise” is used herein to mean including the method, blocks or elements identified, but that such blocks or elements do not comprise an exclusive list and a method or apparatus may also contain other blocks or elements.

It is to be understood that the above description is given by way of example only, and that various modifications may be made by a person skilled in the art. The above described specification, examples and data provide a complete description of the structure and use of some embodiments. Although the above specification describes various embodiments with a certain specific feature or makes reference to one or more individual embodiments, a person skilled in the art can make numerous modifications to the presented embodiments without departing from the spirit or scope of protection of this description.

1. A server, configured to:
receive from a user an information describing intended function of spaces of a building;
based on the received information describing said intended function, the server is further automatically configured to:
transform the information describing said function into information describing spaces of a virtual building and requirements for the building project;
wherein the server is further configured to determine in the transformation, as a requirement for the spaces and the building project, size, purpose and properties of the space on the basis of said function;
wherein the server is further configured to determine the transformation based on events of the spaces, wherein the event represents the purpose, and wherein each event corresponds to a serviceability of the space, and each event includes value functions for the properties of the space in terms of an implementation of the space;
wherein the server is further configured to determine the transformation based on a combination of the value functions of each event for the space;
transform the information describing the spaces of the virtual building and the requirements for the building project into information describing massing of the virtual building;
transform the information describing the massing of the virtual building into building elements and usage elements of the virtual building, wherein said virtual building corresponds to a physical building and its use, wherein the virtual building is obtained on the basis of said transformations a previous transformation being the basis for the next transformation without building information model, BIM;
wherein said virtual building is configured to be provided automatically by the server to the user based on only the information being a setpoint information relating to the intended function of the user of the building.

2. The server according to claim 1, further configured to determine a number of the spaces on the basis of a volume of said intended function, or on the basis of a volume and usage time of said intended function.

3. The server according to claim 1, further configured to determine shared use of the spaces.

4. The server according to claim 1, further configured to mass the virtual building on the basis of the properties of the spaces and the number of stories and location of certain spaces as modelled from the purpose of use.

5. The server according to claim 1, further configured to determine systems of the building on the basis of the virtual building.

6. The server according to claim 1, further configured to determine consumption for the use phase of the building on the basis of the virtual building.

7. A method, comprising:
receiving, from a user by a server, an information describing intended function of spaces of a building;
based on the received information describing said intended function:
transforming, automatically by the server, the information model describing said function into an information model describing spaces of a virtual building and requirements for the building project, wherein the server is further configured to determine in the transformation, as a requirement for the spaces and the building project, the size, purpose and properties of the space on the basis of said function;
wherein the server further determines the transformation based on events of the spaces, wherein the event represents the purpose, and wherein each event corresponds to a serviceability of the space, and each event includes value functions for the properties of the space in terms of an implementation of the space;
wherein the server further determines the transformation based on a combination of the value functions of each event for the space;
transforming, automatically by the server, the information describing the spaces of the virtual building and the requirements for the building project into information describing massing of the virtual building;
transforming, automatically by the server, the information describing the spaces of the virtual building and the requirements for the building project and its massing into its building elements and usage elements, wherein said virtual building corresponds to a physical building, whereby the virtual building is obtained on the basis of said transformations a previous transformation being the basis for the next transformation without building information model, BIM;
wherein said virtual building is configured to be provided automatically by the server to the user based on only the information being a setpoint information relating to the intended function of the user of the building.

8. A computer program product, comprising:
a computer usable medium having computer readable program code means embodied therein for causing:
receiving, from a user by a server, an information describing intended function of spaces of a building;
based on the received information describing said intended function:
transforming, automatically by the serve, the information model describing said function into an information model describing spaces of a virtual building and requirement for the building project, wherein the serve is further configured to determine in the transformation, as a requirement for the spaces and the building project, the size, purpose and properties of the space on the basis of said function;
wherein the server further determines the transformation based on events of the spaces, wherein the event represents the purpose, and wherein each event corresponds to a serviceability of the space, and each event includes value functions for the properties of the space in terms of an implementation of the space;
wherein the server further determines the transformation based on a combination of the value functions of each event for the space;
transforming, automatically by the server, the information describing the spaces of the virtual building and the requirements for the building project into information describing massing of the virtual building;
transforming, automatically by the server, the information describing the spaces of the virtual building and the requirements for the building project and its massing into its building elements and usage elements, wherein said virtual building corresponds to a physical building, whereby the virtual building is obtained on the basis of said transformations a previous transformation being the basis for the next transformation without building information model, BIM;
wherein said virtual building is configured to be provided automatically by the server to the user based on only the information being a setpoint information relating to the intended function of the user of the building.
